(19) United States
(12) Patent Application Publication
(10) Pub. No.: US 2021/0054158 A1
(43) Pub. Date: Feb. 25, 2021

(54) PREPREG, COPPER-CLAD LAMINATE AND PRINTED CIRCUIT BOARD

(71) Applicant: AAC Technologies Pte. Ltd., Singapore City (SG)

(72) Inventors: Hongyuan Wang, Shenzhen (CN); Hezhi Wang, Shenzhen (CN); Yilan Zhang, Shenzhen (CN)

(21) Appl. No.: 16/992,100

(22) Filed: Aug. 13, 2020

(30) Foreign Application Priority Data
Aug. 21, 2019 (CN) 201910772922.7

(51) Int. Cl. C08J 5/24; C08L 47/00; C08L 9/06; H05K 1/03; B32B 5/02; B32B 15/14; B32B 15/20; B32B 17/04

(52) U.S. Cl. CPC C08J 5/24; B32B 2264/1022; C08L 9/06; H05K 1/0373; B32B 5/024; B32B 15/14; B32B 15/20; B32B 17/04; C08J 2347/00; C08J 2309/06; C08J 2471/12; H05K 2201/012; B32B 2260/021; B32B 2260/046; B32B 2262/101; B32B 2457/08; B32B 2264/02; B32B 2307/3065; B32B 2264/1021; C08L 47/00

(57) ABSTRACT

A prepreg is a blend of a fiber reinforcement, a matrix resin and a filler. Based on 100 parts by mass of the prepreg, the fiber reinforcement is 20-60 parts by mass, the matrix resin is 20-65 parts by mass, and the filler is 10-40 parts by mass. The filler is a flame-retardant organic microsphere or a blend of the flame-retardant organic microsphere and an inorganic filler, and the particle size of the filler is preferably 0.1 microns to 15 microns. A copper-clad laminate and a printed circuit board are also disclosed. In various embodiments, the stability of material properties of the prepreg can be improved, the prepreg manufacturing process is simplified, the prepreg production efficiency is improved. Due to the high production efficiency of the prepreg, the manufacturing cost of the prepreg, the copper-clad laminate and the printed circuit board can be reduced.

### CROSS REFERENCE TO RELATED APPLICATIONS

This non-provisional patent application is a Continuation application of International Application PCT/CN2019/104826, filed on Sep. 9, 2019, which claims priority from Patent Application No. 201910772922.7 filed in The People's Republic of China on Aug. 21, 2019. These two applications are incorporated herein by reference.

### TECHNICAL FIELD

The present invention relates generally to the technical field of copper-clad laminates and, in particular, to a prepreg, a copper-clad laminate and a printed circuit board.

### BACKGROUND

In recent years, with the development of electronic information technologies, the miniaturization and high density installation of electronic devices, and the large capacity and high speed transmission of information have been putting forward increasingly higher requirements on the comprehensive performance of printed circuit boards, such as heat resistance, water absorption, chemical resistance, mechanical properties, dimensional stability and dielectric properties.

In the related art, a printed circuit board is made from a copper-clad laminate, and the copper-clad laminate includes a resin substrate and a copper foil attached to the resin substrate. In the manufacture of the resin substrate, it is often necessary to add an inorganic filler into the matrix resin to adjust the dielectric constant of the material, improve the thermodynamic properties of the material and reduce the cost.

However, in the related art, the commonly used inorganic filler, such as silicon dioxide, is mostly a spherical structure with a smooth surface, which leads to problems such as agglomeration and a poor interface performance during the process of mixing the inorganic filler with an organic polymer, resulting in sedimentation of the filler and unstable material properties of the resin substrate. Furthermore, the compatibility between the inorganic filler and the organic polymer is poor, so that it needs to modify the inorganic filler. However, the modification process is complicated, and the production efficiency is low.

Therefore, it is necessary to provide a new prepreg, a copper-clad laminate and a printed circuit board to solve the aforementioned technical problems.

### SUMMARY

Accordingly, the present disclosure is directed to a prepreg, a copper-clad laminate and a printed circuit which can solve at least one of the aforementioned problems.

In one independent aspect, a prepreg is provided which is a blend of a fiber reinforcement, a matrix resin and a filler. Based on 100 parts by mass of the prepreg, the fiber reinforcement has a content of 20-60 parts by mass, the matrix resin has a content of 20-65 parts by mass, and the filler has a content of 10-40 parts by mass. The filler is a flame-retardant organic microsphere or a blend of the flame-retardant organic microsphere and an inorganic filler, and the particle size of the filler is preferably 0.1 microns to 15 microns.

More preferably, the particle size of the filler is 0.1 microns to 5 microns.

In one embodiment, the filler is a blend of the flame-retardant organic microsphere and the inorganic filler, and the content of the flame-retardant organic microsphere is 20%-100% of the blend.

In one embodiment, the flame-retardant organic microsphere comprises an organic flame-retardant microsphere; the organic flame-retardant microsphere is insoluble in a toluene solvent, an acetone solvent, a butanone solvent and an ethanol solvent; and the inorganic filler is any one of silicon dioxide and titanium dioxide.

In one embodiment, the organic flame-retardant microsphere is at least one of a halogen-containing organic microsphere, a phosphorus-containing organic microsphere, a phosphorus-nitrogen-containing organic microsphere and an organosilicon microsphere; and the thermal decomposition temperature of the organic flame-retardant microsphere is above 350° C.

In one embodiment, the matrix resin comprises modified polyphenylene ether, a polyolefin resin and an initiator; and based on 100 parts by mass of the matrix resin, the modified polyphenylene ether is 20-70 parts by mass, the polyolefin resin is 30-70 parts by mass, and the initiator is 0-5 parts by mass.

In one embodiment, the modified polyphenylene ether is low molecular weight polyphenylene ether which is terminated by a reactive functional group; and the reactive functional group comprises any one of an unsaturated ester and an unsaturated olefin.

In one embodiment, the molecular weight of the low molecular weight polyphenylene ether is 800-6000.

In one embodiment, the molecular weight of the low molecular weight polyphenylene ether is 900-4000.

In one embodiment, the polyolefin resin comprises any one or more of polydicyclopentadiene, polydivinylbenzene, polybutadiene and styrene.

In one embodiment, the initiator is a radical initiator, and the initiator is any one of a peroxide initiator, an azo-initiator, and bicummyl.

In one embodiment, the fiber reinforcement comprises any one of a non-woven fabric, a fiber cloth, a fiber felt and a unidirectional fiber cloth made of fibers.

In one embodiment, the fiber is at least one of a glass fiber, a quartz fiber, and an organic fiber.

In another independent aspect, a copper-clad laminate is provided which includes at least one laminated prepreg, and at least one copper foil attached to one side or both sides of the laminated prepreg. The prepreg is a blend of a fiber reinforcement, a matrix resin and a filler. Based on 100 parts by mass of the prepreg, the fiber reinforcement may have a content of 20-60 parts by mass, the matrix resin may have a content of 20-65 parts by mass, and the filler may have a content of 10-40 parts by mass. The filler is a flame-retardant organic microsphere or a blend of the flame-retardant organic microsphere and an inorganic filler, and the particle size of the filler may be 0.1 microns to 15 microns.

In still another independent aspect, a printed circuit board is provided which includes a copper-clad laminate. The copper-clad laminate includes at least one laminated prepreg, and at least one copper foil attached to one side or both sides of the laminated prepreg. The prepreg is a blend of a fiber reinforcement, a matrix resin and a filler. Based on 100 parts by mass of the prepreg, the fiber reinforcement may have a content of 20-60 parts by mass, the matrix resin may have a content of 20-65 parts by mass, and the filler may have a content of 10-40 parts by mass. The filler is a flame-retardant organic microsphere or a blend of the flame-retardant organic microsphere and an inorganic filler, and the particle size of the filler may be 0.1 microns to 15 microns.

Compared with the prepreg in the related art, the prepreg of the present disclosure is a blend of a fiber reinforcement, a matrix resin and a filler. Based on 100 parts by mass of the prepreg, the fiber reinforcement has a content of 20-60 parts by mass, the matrix resin has a content of 20-65 parts by mass, and the filler has a content of 10-40 parts by mass. The filler is a flame-retardant organic microsphere or a blend of the flame-retardant organic microsphere and an inorganic filler, and the particle size of the filler is 0.1 microns to 15 microns. In the aforementioned prepreg, the flame-retardant organic microsphere is filled in the matrix resin. Due to the excellent interface performance between the flame-retardant organic microsphere and the matrix resin, the filler is uniformly distributed in the matrix resin, and sedimentation between the flame-retardant organic microsphere and the matrix resin is not easy to occur, thereby improving the stability of material properties of the prepreg. Furthermore, the flame-retardant organic microsphere and the matrix resin can be directly mixed in a solution, which simplifies the manufacturing process and effectively improves the production efficiency of the prepreg. In the copper-clad laminate and printed circuit board of the present disclosure, the application of the prepreg can effectively ensure the performance stability of the copper-clad laminate and the printed circuit board. Meanwhile, due to the high production efficiency of the prepreg, the manufacturing cost of the prepreg, the copper-clad laminate and the printed circuit board can be reduced.

Independent features and/or independent advantages of this disclosure may become apparent to those skilled in the art upon review of the detailed description and claims.

### DESCRIPTION OF THE EMBODIMENTS

Embodiments of the present disclosure will be clearly and completely described in the following. Apparently, the described embodiments are merely part rather than all of the embodiments of the present disclosure. All other embodiments obtained by persons of ordinary skill in the art based on the embodiments disclosed herein without creative efforts shall be regarded as falling within the protection scope of the present disclosure.

The present disclosure provides a prepreg which is a blend of a fiber reinforcement, a matrix resin and a filler. Based on 100 parts by mass of the prepreg, the fiber reinforcement has a content of 20-60 parts by mass, the matrix resin has a content of 20-65 parts by mass, and the filler has a content of 10-40 parts by mass.

The filler can be a flame-retardant organic microsphere, or a blend of a flame-retardant organic microsphere and an inorganic filler, which can be set according to actual requirements.

For example, in this embodiment, in order to ensure the material properties of the prepreg, the filler can be a blend of the flame-retardant organic microsphere and the inorganic filler, and the content of the flame-retardant organic microsphere is 20%-100% of the blend. As the inorganic filler is added into the filler, the dielectric constant and thermodynamic properties of the prepreg can be effectively improved without affecting the heat resistance and mechanical properties of the matrix resin. More particularly, the inorganic filler is any one of silicon dioxide and titanium dioxide, which can be specifically selected according to actual requirements.

Further, the flame-retardant organic microsphere includes an organic flame-retardant microsphere which is insoluble in a toluene solvent, an acetone solvent, a butanone solvent and an ethanol solvent.

Particularly, the organic flame-retardant microsphere has flame retardancy, including, but not limited to, at least one of a halogen-containing organic microsphere, a phosphorus-containing organic microsphere, a phosphorus-nitrogen-containing organic microsphere and an organosilicon microsphere that have good flame retardancy. In practical application, the types of the organic flame-retardant microsphere can be specifically selected according to needs.

It is worth mentioning that the flame-retardant organic microsphere also has strong heat resistance, and its thermal decomposition temperature is above 350° C. This heat resistance ensures the reliability of filling the flame-retardant organic microsphere in the matrix resin.

The flame-retardant organic microsphere is used as an organic filler, and the flame-retardant organic microsphere does not chemically react with the matrix resin. Compared with other soluble or reactive flame-retardants, the insoluble organic flame-retardant microsphere has the advantages of low cost, little influence on heat resistance, mechanical properties and dielectric properties of a composite material, good flame-retardant effect and the like.

The heat resistance and mechanical properties of the matrix resin are guaranteed, and meanwhile the interface strength between the flame-retardant organic microsphere and the matrix resin is increased, the interface performance between them is thus improved, and the problems of agglomeration and sedimentation are not easy to occur, such that the filler can be effectively filled in the matrix resin uniformly, and the stability of material properties of the prepreg is effectively improved. At the same time, the filler can be directly mixed with the matrix resin in a solution without treatment procedures such as ultrasonic treatment, grinding or high-speed stirring, thereby simplifying the mixing process, greatly improving the production efficiency and reducing the production cost of the prepreg. Furthermore, the flame-retardant organic microsphere has a strong flame-retardant performance, such that the flame retardancy of the prepreg is greatly improved while ensuring the heat resistance and thermal performance of the matrix resin.

In the prepreg, if the content of the flame-retardant organic microsphere is too low, the flame retardancy of the prepreg will be decreased. That is, the flame retardancy level of the prepreg will not reach the UL94-V0 level (which is the standard requirement for flame retardancy in the copper-clad laminate industry). However, the content of the flame-retardant organic microsphere being too high will also increase the cost. Therefore, in the prepreg of the present disclosure, the content of the filler is 0-40 parts by mass, and the content of the flame-retardant organic microsphere accounts for 20%-100% of the content of the filler, which can effectively improve the flame retardancy of the prepreg, and the specific content of the flame-retardant organic microsphere can be set according to the actual use requirements.

In order to further improve the flame retardancy of the flame-retardant organic microsphere, as a preferred embodiment, the flame-retardant organic microsphere is a mixture formed by the organic flame-retardant microsphere and a flame-retardant synergist, and the flame retardancy of the prepreg can be effectively increased by adding the flame-retardant synergist.

It is worth mentioning that the filler is mainly granular due to the influence of the flame-retardant organic microsphere, and the particle size of the filler also directly affects the stability of the filler after it is mixed with the matrix resin. By reducing the particle size of the filler, the stability of the mixing of the filler and the matrix resin can be effectively improved. Here, as a preferred embodiment, the particle size of the filler is 0.1 microns to 15 microns, and more preferably, the particle size of the filler is 0.1 microns to 5 microns.

By controlling the particle size of the filler, the filler can be effectively distributed in the matrix resin more evenly, and the interface strength between the organic filler and the matrix resin can be further improved, such that the stability of the material properties of the prepreg is higher, and the flame retardancy of the prepreg is greatly improved.

The matrix resin includes modified polyphenylene ether, a polyolefin resin and an initiator. Based on 100 parts by mass of the matrix resin, the modified polyphenylene ether has a content of 20-70 parts by mass, the polyolefin resin has a content of 30-70 parts by mass, and the initiator has a content of 0-5 parts by mass.

More particularly, the modified polyphenylene ether is low molecular weight polyphenylene ether which is terminated by a reactive functional group, and the reactive functional group includes any one of an unsaturated ester and an unsaturated olefin, which can be specifically selected according to actual requirements. Preferably, the molecular weight of the low molecular weight polyphenylene ether is 800-6000; and more preferably, the molecular weight of the low molecular weight polyphenylene ether is 900-4000.

The polyolefin resin includes any one of polydicyclopentadiene, polydivinylbenzene, polybutadiene and styrene, which can be specifically selected according to actual requirements.

In the matrix resin, modified polyphenylene ether has high viscosity but poor manufacturability, while the polyolefin resin is a liquid resin with excellent dielectric properties, so the polyolefin resin and the modified polyphenylene ether are blended under the action of an initiator to form the matrix resin. The polyolefin resin and the modified polyphenylene ether can effectively improve the manufacturability of the resin and reduce the production cost of the matrix resin to a certain extent.

The initiator is a free radical initiator, and the initiator is any one of a peroxide initiator, an azo-initiator and bicummyl, which can be specifically selected according to actual requirements.

The fiber reinforcement includes any one of a non-woven fabric, a fiber cloth, a fiber felt and a unidirectional fiber cloth made of fibers; and the fiber is at least one of a glass fiber, a quartz fiber and an organic fiber.

The present disclosure also provides a copper-clad laminate which includes at least one laminated prepreg according to the present disclosure and at least one copper foil attached to one side or both sides of the laminated prepreg. The properties of the prepreg as the basic material for manufacturing the copper-clad laminate directly affect the properties of the copper-clad laminate.

The present disclosure also provides a printed circuit board, which includes the copper-clad laminate according to the present disclosure. The copper-clad laminate is manufactured into the printed circuit board sequentially through the procedures of exposing, developing, etching, surface treatment and the like. The printed circuit board has better dielectric properties.

In the prepreg, copper-clad laminate and printed circuit board described above, the application of the prepreg can effectively ensure the stability of the properties of the copper-clad laminate and the printed circuit board, so that the copper-clad laminate and the printed circuit board have better dielectric properties, heat resistance, mechanical properties and flame retardancy. Meanwhile, due to the high production efficiency and low production cost of the prepreg, the manufacturing cost of the copper-clad laminate and printed circuit board are reduced.

In order to verify the implementation effect of the prepreg according to the present disclosure, a comparison between the following groups of comparative embodiments and embodiments is carried out. Short names which are not specifically explained are all short names of products well known to those skilled in the art.

TABLE 1
Compositions among each embodiment and each comparative embodiment

| | | | | | | | | | | | | | | | The first | | The second | |
|---|---|---|---|---|---|---|---|---|---|---|---|---|---|---|---|---|---|---|
| | The first | | The second | | The third | | The fourth | | The fifth | | The sixth | | The seventh | | comparative | | comparative | |
| | embodiment | | embodiment | | embodiment | | embodiment | | embodiment | | embodiment | | embodiment | | embodiment | | embodiment | |
| PPO | 20 | parts | 20 | parts | 20 | parts | 20 | parts | 20 | parts | 20 | parts | 20 | parts | 20 | parts | 20 | parts |
| (polyphenylene | | | | | | | | | | | | | | | | | | |
| ether) | | | | | | | | | | | | | | | | | | |
| Polydivinylbenzene | 30 | parts | 30 | parts | 30 | parts | | | | | | | | | 30 | parts | | |
| Styrene-butadiene | | | | | | | 30 | parts | 30 | parts | 30 | parts | 30 | parts | | | 30 | parts |
| rubber | | | | | | | | | | | | | | | | | | |
| Silicon dioxide | 19 | parts | 16 | parts | | | 19 | parts | 14 | parts | | | 16 | parts | 24 | parts | 24 | parts |
| Bromine-containing | 5 | parts | 8 | parts | 24 | parts | | | | | | | 8 | parts | | | | |
| organic microsphere | | | | | | | | | | | | | | | | | | |
| Phosphorus- | | | | | | | 5 | parts | 10 | parts | 24 | parts | | | | | | |
| nitrogen-containing | | | | | | | | | | | | | | | | | | |
| organic microsphere | | | | | | | | | | | | | | | | | | |

| | | | | | | | | |
|---|---|---|---|---|---|---|---|---|
| Fiber cloth | 26 parts | 26 parts | 26 parts | 26 parts | 26 parts | 26 parts | 26 parts | 26 parts |
| | (2116 | (2116 | (2116 | (2116 | (2116 | (2116 | (2116 | (2116 |
| | electronic- | electronic- | electronic- | electronic- | electronic- | electronic- | electronic- | electronic- |
| | grade glass | grade glass | grade glass | grade glass | grade glass | grade glass | grade glass | grade glass |
| | fiber) | fiber) | fiber) | fiber) | fiber) | fiber) | fiber) | fiber) |

### The First Embodiment

As shown in Table 1 above, based on 100 parts by mass of the prepreg of the first embodiment, the prepreg specifically includes 20 parts by mass of polyphenylene ether, 30 parts by mass of polydivinylbenzene, 19 parts by mass of silicon dioxide, 5 parts by mass of a bromine-containing organic microsphere, and 26 parts by mass of a fiber cloth.

Particularly, the polyphenylene ether and the polydivinylbenzene together form a matrix resin, and the polyphenylene ether is a polyphenylene ether terminated by an acrylate and has a molecular weight of preferably 2200-2400.

The molecular weight of the polydivinylbenzene is 10000-160000.

The silicon dioxide is the inorganic filler, and has a particle size of 0.1 microns to 0.3 microns. The bromine-containing organic microsphere is the organic flame-retardant microsphere. The bromine-containing organic microsphere and the silicon dioxide together constitute the filler of the first embodiment.

The fiber cloth is used as the fiber reinforcement, and is preferably an electronic-grade E glass fiber.

In the above structure, the polyphenylene ether has high viscosity, while the polydivinylbenzene is in a liquid state and has excellent dielectric properties. Blending the polyphenylene ether with the polydivinylbenzene can effectively improve the manufacturability of the matrix resin and reduce the cost of manufacturing the matrix resin of the first embodiment. The insoluble bromine-containing organic microsphere has the advantages of low cost, little influence on the heat resistance, mechanical properties and dielectric properties of the composite material, good flame-retardant effect, etc. The addition of the bromine-containing organic microsphere not only ensures the heat resistance, mechanical properties and dielectric properties of the prepreg of the first embodiment, but it also effectively enhances the flame retardancy of the prepreg of the first embodiment.

### The Second Embodiment

As shown in Table 1 above, based on 100 parts by mass of the prepreg of the second embodiment, the prepreg specifically includes 20 parts by mass of polyphenylene ether, 30 parts by mass of polydivinylbenzene, 16 parts by mass of silicon dioxide, 8 parts by mass of a bromine-containing organic microsphere, and 26 parts by mass of a fiber cloth.

Particularly, the polyphenylene ether and the polydivinylbenzene together form a matrix resin, and the polyphenylene ether is a polyphenylene ether terminated by an acrylate and has a molecular weight of preferably 2200-2400.

The molecular weight of the polydivinylbenzene is 10000-160000.

The silicon dioxide is the inorganic filler, and has a particle size of 0.1 microns to 0.3 microns. The bromine-containing organic microsphere is the organic flame-retardant microsphere. The bromine-containing organic microsphere and the silicon dioxide together constitute the filler of the second embodiment.

The fiber cloth is used as the fiber reinforcement, and is preferably an electronic-grade E glass fiber.

In the above structure, the polyphenylene ether has high viscosity, while the polydivinylbenzene is in a liquid state and has excellent dielectric properties. Blending the polyphenylene ether with the polydivinylbenzene can effectively improve the manufacturability of the matrix resin and reduce the cost of manufacturing the matrix resin of the second embodiment. The insoluble bromine-containing organic microsphere has the advantages of low cost, little influence on the heat resistance, mechanical properties and dielectric properties of the composite material, good flame-retardant effect, etc. The addition of the bromine-containing organic microsphere not only ensures the heat resistance, mechanical properties and dielectric properties of the prepreg of the second embodiment, but it also effectively enhances the flame retardancy of the prepreg of the second embodiment.

### The Third Embodiment

As shown in Table 1 above, based on 100 parts by mass of the prepreg of the third embodiment, the prepreg specifically includes 20 parts by mass of polyphenylene ether, 30 parts by mass of polydivinylbenzene, 24 parts by mass of a bromine-containing organic microsphere, and 26 parts by mass of a fiber cloth.

Particularly, the polyphenylene ether and the polydivinylbenzene together form a matrix resin, and the polyphenylene ether is a polyphenylene ether terminated by an acrylate and has a molecular weight of preferably 2200-2400. The molecular weight of the polydivinylbenzene is 10000-160000.

The bromine-containing organic microsphere is the organic flame-retardant microsphere. The bromine-containing organic microsphere acts as the filler of the third embodiment.

The fiber cloth is used as the fiber reinforcement, and is preferably an electronic-grade E glass fiber.

In the above structure, the polyphenylene ether has high viscosity, while the polydivinylbenzene is in a liquid state and has excellent dielectric properties. Blending the polyphenylene ether with the polydivinylbenzene can effectively improve the manufacturability of the matrix resin and reduce the cost of manufacturing the matrix resin of the third embodiment. The insoluble bromine-containing organic microsphere has the advantages of low cost, little influence on the heat resistance, mechanical properties and dielectric properties of the composite material, good flame-retardant effect, etc. The addition of the bromine-containing organic microsphere not only ensures the heat resistance, mechanical properties and dielectric properties of the prepreg of the third embodiment, but it also effectively enhances the flame retardancy of the prepreg of the third embodiment.

### The Fourth Embodiment

As shown in Table 1 above, based on 100 parts by mass of the prepreg of the fourth embodiment, the prepreg specifically includes 20 parts by mass of polyphenylene ether, 30 parts by mass of styrene-butadiene rubber, 19 parts by mass of silicon dioxide, 5 parts by mass of a phosphorus-nitrogen-containing organic microsphere, and 26 parts by mass of a fiber cloth.

Particularly, the polyphenylene ether and the styrene-butadiene rubber together form a matrix resin, and the polyphenylene ether is a polyphenylene ether terminated by an acrylate and has a molecular weight of preferably 2200-2400.

The silicon dioxide is the inorganic filler, and has a particle size of 0.1 microns to 0.3 microns. The phosphorus-nitrogen-containing organic microsphere is the organic flame-retardant microsphere. The phosphorus-nitrogen-containing organic microsphere and the silicon dioxide together constitute the filler of the fourth embodiment.

The fiber cloth is used as the fiber reinforcement, and is preferably an electronic-grade E glass fiber.

In the above structure, the polyphenylene ether has high viscosity, while the styrene-butadiene rubber is in a liquid state and has excellent dielectric properties. Blending the polyphenylene ether with the styrene-butadiene rubber can effectively improve the manufacturability of the matrix resin and reduce the cost of manufacturing the matrix resin of the fourth embodiment. The insoluble phosphorus-nitrogen-containing organic microsphere has the advantages of low cost, little influence on the heat resistance, mechanical properties and dielectric properties of the composite material, good flame-retardant effect, etc. The addition of the phosphorus-nitrogen-containing organic microsphere not only ensures the heat resistance, mechanical properties and dielectric properties of the prepreg of the fourth embodiment, but it also effectively enhances the flame retardancy of the prepreg of the fourth embodiment. Furthermore, the phosphorus-nitrogen-containing organic microsphere does not contain any halogen element, and thus can meet the halogen-free flame-retardant requirements of the copper-clad laminate.

### The Fifth Embodiment

As shown in Table 1 above, based on 100 parts by mass of the prepreg of the fifth embodiment, the prepreg specifically includes 20 parts by mass of polyphenylene ether, 30 parts by mass of styrene-butadiene rubber, 14 parts by mass of silicon dioxide, 10 parts by mass of a phosphorus-nitrogen-containing organic microsphere, and 26 parts by mass of a fiber cloth.

Particularly, the polyphenylene ether and the styrene-butadiene rubber together form a matrix resin, and the polyphenylene ether is a polyphenylene ether terminated by an acrylate and has a molecular weight of preferably 2200-2400.

The silicon dioxide is the inorganic filler, and has a particle size of 0.1 microns to 0.3 microns. The phosphorus-nitrogen-containing organic microsphere is the organic flame-retardant microsphere. The phosphorus-nitrogen-containing organic microsphere and the silicon dioxide together constitute the filler of the fifth embodiment.

The fiber cloth is used as the fiber reinforcement, and is preferably an electronic-grade E glass fiber.

In the above structure, the polyphenylene ether has high viscosity, while the styrene-butadiene rubber is in a liquid state and has excellent dielectric properties. Blending the polyphenylene ether with the styrene-butadiene rubber can effectively improve the manufacturability of the matrix resin and reduce the cost of manufacturing the matrix resin of the fifth embodiment. The insoluble phosphorus-nitrogen-containing organic microsphere has the advantages of low cost, little influence on the heat resistance, mechanical properties and dielectric properties of the composite material, good flame-retardant effect, etc. The addition of the phosphorus-nitrogen-containing organic microsphere not only ensures the heat resistance, mechanical properties and dielectric properties of the prepreg of the fifth embodiment, but it also effectively enhances the flame retardancy of the prepreg of the fifth embodiment. Furthermore, the phosphorus-nitrogen-containing organic microsphere does not contain any halogen element, and thus can meet the halogen-free flame-retardant requirements of the copper-clad laminate.

### The Sixth Embodiment

As shown in Table 1 above, based on 100 parts by mass of the prepreg of the sixth embodiment, the prepreg specifically includes 20 parts by mass of polyphenylene ether, 30 parts by mass of styrene-butadiene rubber, 24 parts by mass of a phosphorus-nitrogen-containing organic microsphere, and 26 parts by mass of a fiber cloth.

Particularly, the polyphenylene ether and the styrene-butadiene rubber together form a matrix resin, and the polyphenylene ether is a polyphenylene ether terminated by an acrylate and has a molecular weight of preferably 2200-2400.

The phosphorus-nitrogen-containing organic microsphere is the organic flame-retardant microsphere. The phosphorus-nitrogen-containing organic microsphere acts as the filler of the sixth embodiment.

The fiber cloth is used as the fiber reinforcement, and is preferably an electronic-grade E glass fiber.

In the above structure, the polyphenylene ether has high viscosity, while the styrene-butadiene rubber is in a liquid state and has excellent dielectric properties. Blending the polyphenylene ether with the styrene-butadiene rubber can effectively improve the manufacturability of the matrix resin and reduce the cost of manufacturing the matrix resin of the sixth embodiment. The insoluble phosphorus-nitrogen-containing organic microsphere has the advantages of low cost, little influence on the heat resistance, mechanical properties and dielectric properties of the composite material, good flame-retardant effect, etc. The addition of the phosphorus-nitrogen-containing organic microsphere not only ensures the heat resistance, mechanical properties and dielectric properties of the prepreg of the sixth embodiment, but it also effectively enhances the flame retardancy of the prepreg of the sixth embodiment. Furthermore, the phosphorus-nitrogen-containing organic microsphere does not contain any halogen element, and thus can meet the halogen-free flame-retardant requirements of the copper-clad laminate.

### The Seventh Embodiment

As shown in Table 1 above, based on 100 parts by mass of the prepreg of the seventh embodiment, the prepreg specifically includes 20 parts by mass of polyphenylene ether, 30 parts by mass of styrene-butadiene rubber, 16 parts by mass of silicon dioxide, 8 parts by mass of a bromine-containing organic microsphere, and 26 parts by mass of a fiber cloth.

Particularly, the polyphenylene ether and the styrene-butadiene rubber together form a matrix resin, and the polyphenylene ether is a polyphenylene ether terminated by an acrylate and has a molecular weight of preferably 2200-2400.

The silicon dioxide is the inorganic filler, and has a particle size of 0.1 microns to 0.3 microns. The bromine-containing organic microsphere is the organic flame-retardant microsphere. The bromine-containing organic microsphere and the silicon dioxide together constitute the filler of the seventh embodiment.

The fiber cloth is used as the fiber reinforcement, and is preferably an electronic-grade E glass fiber.

In the above structure, the polyphenylene ether has high viscosity, while the styrene-butadiene rubber is in a liquid state and has excellent dielectric properties. Blending the polyphenylene ether with the styrene-butadiene rubber can effectively improve the manufacturability of the matrix resin and reduce the cost of manufacturing the matrix resin of the seventh embodiment. The insoluble bromine-containing organic microsphere has the characteristics of low cost, little influence on the heat resistance, mechanical properties and dielectric properties of the composite material, good flame-retardant effect, etc. The addition of the bromine-containing organic microsphere not only ensures the heat resistance, mechanical properties and dielectric properties of the prepreg of the seventh embodiment, but it also effectively enhances the flame retardancy of the prepreg of the seventh embodiment.

### The First Comparative Embodiment

As shown in Table 1 above, based on 100 parts by mass of the prepreg of the first comparative embodiment, the prepreg specifically includes 20 parts by mass of polyphenylene ether, 30 parts by mass of polydivinylbenzene, 24 parts by mass of silicon dioxide, and 26 parts by mass of a fiber cloth.

Particularly, the polyphenylene ether and the polydivinylbenzene together form a matrix resin. The polyphenylene ether is a polyphenylene ether terminated by an acrylate, and has a molecular weight of preferably 2200-2400. The molecular weight of the polydivinylbenzene is preferably 10000-160000. The silicon dioxide is the inorganic filler, and the particle size of the silicon dioxide is 0.1 microns to 0.3 microns. The fiber cloth, as the fiber reinforcement, is preferably an electronic-grade E glass fiber.

### The Second Comparative Embodiment

As shown in Table 1 above, based on 100 parts by mass of the prepreg of the second comparative embodiment, the prepreg specifically includes 20 parts by mass of polyphenylene ether, 30 parts by mass of styrene-butadiene rubber, and 26 parts by mass of a fiber cloth.

Particularly, the polyphenylene ether and the polydivinylbenzene together form a matrix resin, and the polyphenylene ether is a polyphenylene ether terminated by an acrylate and has a molecular weight of preferably 2200-2400. The fiber cloth, as the fiber reinforcement, is preferably an electronic-grade E glass fiber.

TABLE 2
Comparison between the properties of embodiments and comparative embodiments

| | | | | | | | | The first | The second |
|---|---|---|---|---|---|---|---|---|---|
| | The first | The second | The third | The fourth | The fifth | The sixth | The seventh | comparative | comparative |
| | embodiment | embodiment | embodiment | embodiment | embodiment | embodiment | embodiment | embodiment | embodiment |
| Water absorption | 0.059% | 0.054% | 0.050% | 0.052% | 0.06% | 0.075% | 0.056% | 0.08% | 0.08% |
| Glass-transition | 212 | 217 | 215 | 219 | 218 | 206 | 215 | 216 | 220 |
| temperature (Tg) | | | | | | | | | |
| (° C.) | | | | | | | | | |
| Flame retardancy | UL94-V0 | UL94-V0 | UL94-V0 | UL94-V1 | UL94-V0 | UL94-V0 | UL94-V0 | Inflammable | Inflammable |
| Copper peel | 0.62 N/mm | 0.66 N/mm | 0.71 N/mm | 0.69 N/mm | 0.70 N/mm | 0.75 N/mm | 0.61 N/mm | 0.68 N/mm | 0.64 N/mm |
| strength at 180° C. | | | | | | | | | |
| Dielectric | 3.24 | 3.22 | 3.25 | 3.14 | 3.12 | 3.20 | 3.18 | 3.41 | 3.26 |
| constant (1 GHz) | | | | | | | | | |
| Dielectric loss | 0.0021 | 0.0021 | 0.0023 | 0.0019 | 0.0017 | 0.0022 | 0.0021 | 0.0026 | 0.0024 |
| tangent (1 GHz) | | | | | | | | | |

Referring to both the above Table 1 and Table 2, the water absorption, heat resistance, copper peel strength and dielectric properties of the composite materials prepared from the prepreg of the first embodiment, the prepreg of the second embodiment, the prepreg of the third embodiment, the prepreg of the fourth embodiment, the prepreg of the fifth embodiment, the prepreg of the sixth embodiment, the prepreg of the seventh embodiment, the prepreg of the first comparative embodiment and the prepreg of the second comparative embodiment are basically kept at the similar levels. However, the flame retardancy of the composite material prepared from the prepreg of each embodiment filled with the organic microsphere is significantly improved. The flame retardancy of the composite material prepared from each of the prepreg of the first embodiment, the prepreg of the second embodiment, the prepreg of the third embodiment, the prepreg of the fifth embodiment, the prepreg of the sixth embodiment, and the prepreg of the seventh embodiment can reach the UL94-V0 level. The flame retardancy of the composite material prepared from the prepreg of the fourth embodiment can reach the UL94-V1 level. The flame retardancy is obviously better than that of the composite materials prepared from the prepregs of the comparative embodiment 1 and the comparative embodiment 2. Therefore, to sum up, the prepreg filled with the organic flame-retardant microsphere can effectively improve its own flame retardancy while maintaining its good material properties.

Compared with the preg in the related art, the prepreg of the present disclosure is a blend of a fiber reinforcement, a matrix resin and a filler. The fiber reinforcement is 20-60 parts by mass, the matrix resin is 20-65 parts by mass, and the filler is 10-40 parts by mass. The filler is a flame-retardant organic microsphere or a blend of the flame-retardant organic microsphere and an inorganic filler, and the particle size of the filler is 0.1 microns to 15 microns. In the aforementioned prepreg, the flame-retardant organic microsphere is filled in the matrix resin. Due to the excellent interface performance between the flame-retardant organic microsphere and the matrix resin, the filler is uniformly distributed in the matrix resin, and sedimentation between the flame-retardant organic microsphere and the matrix resin is not easy to occur, thereby improving the stability of material properties of the prepreg. Furthermore, the flame-retardant organic microsphere and the matrix resin can be directly mixed in a solution, which simplifies the manufacturing process and effectively improves the production efficiency of the prepreg. In the copper-clad laminate and printed circuit board of the present disclosure, the application of the prepreg can effectively ensure the performance stability of the copper-clad laminate and the printed circuit board. Meanwhile, due to the high production efficiency of the prepreg, the manufacturing cost of the prepreg, the copper-clad laminate and the printed circuit board can be reduced.

Although the disclosure is described with reference to one or more embodiments, it will be apparent to those skilled in the art that various modifications and variations can be made to the disclosed structure and method without departing from the scope or spirit of the disclosure. In view of the foregoing, it is intended that the present disclosure cover modifications and variations of this invention provided they fall within the scope of the following claims and their equivalents.

What is claimed is:

1. A prepreg, wherein the prepreg is a blend of a fiber reinforcement, a matrix resin and a filler;
wherein, based on 100 parts by mass of the prepreg, the fiber reinforcement has a content of 20-60 parts by mass, the matrix resin has a content of 20-65 parts by mass, and the filler has a content of 10-40 parts by mass;
wherein, the filler is a flame-retardant organic microsphere or a blend of the flame-retardant organic microsphere and an inorganic filler, and the particle size of the filler is 0.1 microns to 15 microns.

2. The prepreg according to claim 1, wherein the particle size of the filler is 0.1 microns to 5 microns.

3. The prepreg according to claim 1, wherein the filler is a blend of the flame-retardant organic microsphere and the inorganic filler, and the content of the flame-retardant organic microsphere is 20%-100% of the blend.

4. The prepreg according to claim 3, wherein the flame-retardant organic microsphere comprises an organic flame-retardant microsphere; the organic flame-retardant microsphere is insoluble in a toluene solvent, an acetone solvent, a butanone solvent and an ethanol solvent; and the inorganic filler is any one of silicon dioxide and titanium dioxide.

5. The prepreg according to claim 4, wherein the organic flame-retardant microsphere is at least one of a halogen-containing organic microsphere, a phosphorus-containing organic microsphere, a phosphorus-nitrogen-containing organic microsphere and an organosilicon microsphere; and the thermal decomposition temperature of the organic flame-retardant microsphere is above 350° C.

6. The prepreg according to claim 1, wherein the matrix resin comprises modified polyphenylene ether, a polyolefin resin and an initiator; and based on 100 parts by mass of the matrix resin, the modified polyphenylene ether has a content of 20-70 parts by mass, the polyolefin resin has a content of 30-70 parts by mass, and the initiator has a content of 0-5 parts by mass.

7. The prepreg according to claim 6, wherein the modified polyphenylene ether is low molecular weight polyphenylene ether which is terminated by a reactive functional group; and the reactive functional group comprises any one of an unsaturated ester and an unsaturated olefin.

8. The prepreg according to claim 7, wherein the molecular weight of the low molecular weight polyphenylene ether is 800-6000.

9. The prepreg according to claim 8, wherein the molecular weight of the low molecular weight polyphenylene ether is 900-4000.

10. The prepreg according to claim 6, wherein the polyolefin resin comprises any one or more of polydicyclopentadiene, polydivinylbenzene, polybutadiene and styrene.

11. The prepreg according to claim 6, wherein the initiator is a radical initiator, and the initiator is any one of a peroxide initiator, an azo-initiator, and bicummyl.

12. The prepreg according to claim 1, wherein the fiber reinforcement comprises any one of a non-woven fabric, a fiber cloth, a fiber felt and a unidirectional fiber cloth made of fibers.

13. The prepreg according to claim 12, wherein the fiber is at least one of a glass fiber, a quartz fiber, and an organic fiber.

14. A copper-clad laminate comprising:
at least one laminated prepreg, the prepreg being a blend of a fiber reinforcement, a matrix resin and a filler, wherein based on 100 parts by mass of the prepreg, the fiber reinforcement has a content of 20-60 parts by mass, the matrix resin has a content of 20-65 parts by mass, and the filler has a content of 10-40 parts by mass, and wherein the filler is a flame-retardant organic microsphere or a blend of the flame-retardant organic microsphere and an inorganic filler, and the particle size of the filler is 0.1 microns to 15 microns and
at least one copper foil attached to one side or both sides of the laminated prepreg.

15. The copper-clad laminate according to claim 14, wherein the particle size of the filler is 0.1 microns to 5 microns.

16. The copper-clad laminate according to claim 14, wherein the filler is a blend of the flame-retardant organic microsphere and the inorganic filler, and the content of the flame-retardant organic microsphere is 20%400% of the blend.

17. The copper-clad laminate according to claim 16, wherein the flame-retardant organic microsphere comprises an organic flame-retardant microsphere; the organic flame-retardant microsphere is insoluble in a toluene solvent, an acetone solvent, a butanone solvent and an ethanol solvent; and the inorganic filler is any one of silicon dioxide and titanium dioxide.

18. A printed circuit board comprising a copper-clad laminate, the copper-clad laminate comprising:
at least one laminated prepreg, the prepreg being a blend of a fiber reinforcement, a matrix resin and a filler, wherein based on 100 parts by mass of the prepreg, the fiber reinforcement has a content of 20-60 parts by mass, the matrix resin has a content of 20-65 parts by mass, and the filler has a content of 10-40 parts by mass, and wherein the filler is a flame-retardant organic microsphere or a blend of the flame-retardant organic microsphere and an inorganic filler, and the particle size of the filler is 0.1 microns to 15 microns and
at least one copper foil attached to one side or both sides of the laminated prepreg.

19. The printed circuit board according to claim 18, wherein the filler is a blend of the flame-retardant organic microsphere and the inorganic filler, and the content of the flame-retardant organic microsphere is 20%-100% of the blend.

20. The printed circuit board according to claim 19, wherein the flame-retardant organic microsphere comprises an organic flame-retardant microsphere; the organic flame-retardant microsphere is insoluble in a toluene solvent, an acetone solvent, a butanone solvent and an ethanol solvent; and the inorganic filler is any one of silicon dioxide and titanium dioxide.
